(19) United States
(12) Patent Application Publication
(10) Pub. No.: US 2025/0258193 A1
(43) Pub. Date: Aug. 14, 2025

(54) METHOD AND APPARATUS FOR AUTOMATED PRODUCTION OF PIEZOELECTRIC ACCELEROMETERS

(71) Applicant: Industrial Consulting Automation Research Engineering SRL, Mons (BE)

(72) Inventors: John D. Bagby, Fairport, NY (US); Fabrice Richard E. Brion, Mons (BE); Robert D. Skeirik, Knoxville, TN (US); François Pascon, La Louviere (BE); Thomas Dubray, Soire Saint-Gery (BE); Thomas Di Pietro, Estinnes-au-Val (BE); Anthony Delattre, Tubize (BE); Marc Rousselle, Frameries (BE); Guiseppe Moi, La Hestre (BE); Sébastien Bruscaglia, Mons (BE)

(21) Appl. No.: 19/046,005

(22) Filed: Feb. 5, 2025

Related U.S. Application Data
(60) Provisional application No. 63/551,837, filed on Feb. 9, 2024.

(51) Int. Cl. G01P 15/09; G01P 15/18; H10N 30/071; H10N 30/30; H10N 30/87

(52) U.S. Cl. CPC G01P 15/09; G01P 15/18; H10N 30/071; H10N 30/302; H10N 30/875

(57) ABSTRACT

Various implementations include a piezoelectric accelerometer assembly including a rigid circuit board, a plurality of piezoelectric sensing elements coupled directly on the circuit board in a single plane, wherein at least two of the piezoelectric sensing elements have measurement axes that are orthogonal to each other, and a charge amplifier circuit coupled on the circuit board and electrically coupled to the piezoelectric sensing elements. The piezoelectric sensing elements may include three elements arranged to measure vibration in three orthogonal axes. A conductive shield may be positioned over the sensing elements and amplifier circuit. The assembly enables automated manufacturing and testing of high-performance accelerometers for industrial applications.

### FIELD OF INVENTION

The present disclosure relates to piezoelectric accelerometers, and more particularly to a method and apparatus for automated production of high-performance piezoelectric accelerometers for Industrial Internet of Things (IIoT) applications.

### BACKGROUND

Vibration measurement is a critical parameter for determining the condition of assets in manufacturing processes, with acceleration sensors being the current state of the art. However, existing accelerometer options fail to meet the complete set of characteristics required for wide-scale implementation in the Industrial Internet of Things (IIoT), including small size, low power consumption, low cost, wide frequency bandwidth, high input range, high resolution, low spectral noise, and compact triaxial configuration. Current designs often require multiple PCB boards, rigid-flex configurations, or manual assembly, compromising either performance or manufacturing cost and complexity. These limitations hinder the potential for manufacturing and installing millions of sensors across industry to provide reliable asset health monitoring.

The global demand for vibration measurement devices is projected to reach 100s of millions within the near future, and existing production methods for piezoelectric sensors, typically involving some amount of hand assembly, are incapable of meeting this demand. To address this, the industry has shifted to micro-electromechanical system (MEMS) sensors, which can be easily mass produced but compromise performance and frequency response resulting in inferior analysis ability. Current MEMS chips are comparatively limited in frequency range which translates into the inability to detect or quantify some defect modes on assets in manufacturing processes. Without this information, the Overall Equipment Effectiveness (OEE) of a plant's equipment may be substantially reduced.

### SUMMARY

Various implementations provide a piezoelectric accelerometer assembly. The assembly includes a rigid circuit board, a plurality of piezoelectric sensing elements, and a charge amplifier circuit. The plurality of piezoelectric sensing elements is coupled directly on the circuit board in a single plane. At least two of the piezoelectric sensing elements have measurement axes that are orthogonal to each other. The charge amplifier circuit is coupled on the circuit board and electrically coupled to the piezoelectric sensing elements.

In some implementations, the plurality of piezoelectric sensing elements includes three piezoelectric sensing elements arranged to measure vibration in three orthogonal axes. In some implementations, two of the three piezoelectric sensing elements are coupled to the circuit board in a configuration to measure vibration in a direction parallel to the single plane and one of the three piezoelectric sensing elements is coupled to the circuit board in a configuration to measure vibration in a direction orthogonal to the single plane.

In some implementations, each piezoelectric sensing element includes a piezoelectric plate, a seismic mass, and a conductive bonding layer securing the piezoelectric plate to the seismic mass. In some implementations, the conductive bonding layer is a first conductive bonding layer, wherein each piezoelectric sensing element further includes a second conductive bonding layer securing the piezoelectric sensing element to the circuit board. In some implementations, the assembly further includes electrical connection wires electrically coupling each seismic mass to the charge amplifier circuit.

In some implementations, the assembly further includes a conductive shield positioned over the piezoelectric sensing elements and the charge amplifier circuit. In some implementations, the circuit board includes a ground plane on a bottom layer and power and signal circuits on an intermediary layer. In some implementations, connection points for the power and signal circuits are accessible outside the conductive shield.

Various other implementations provide a method of manufacturing a piezoelectric accelerometer. The method includes providing a rigid circuit board, coupling a plurality of piezoelectric sensing elements directly on the circuit board in a single plane using surface mount technology (SMT), wherein at least two of the piezoelectric sensing elements have measurement axes that are orthogonal to each other, and coupling a charge amplifier circuit on the circuit board.

In some implementations, coupling the plurality of piezoelectric sensing elements includes coupling three piezoelectric sensing elements arranged to measure vibration in three orthogonal axes. In some implementations, coupling the three piezoelectric sensing elements includes coupling two of the three piezoelectric sensing elements to the circuit board in a configuration to measure vibration in a direction parallel to the single plane and coupling one of the three piezoelectric sensing elements to the circuit board in a configuration to measure vibration in a direction orthogonal to the single plane.

In some implementations, the method further includes applying a conductive bonding material to couple each piezoelectric sensing element to the circuit board. In some implementations, applying the conductive bonding material includes using at least one of: conductive adhesive, solder, or other conductive bonding medium.

In some implementations, the method further includes electrically coupling each piezoelectric sensing element to the charge amplifier circuit using wire bonding. In some implementations, the method further includes positioning a conductive shield over the piezoelectric sensing elements and the charge amplifier circuit on the circuit board.

Various other implementations provide a fixture configured for testing and calibrating piezoelectric accelerometers. The fixture includes an exciter base, a rigid circuit board panel, and a clamping platen. The rigid circuit board panel contains one or more piezoelectric accelerometer assemblies. Each piezoelectric accelerometer assembly includes piezoelectric sensing elements coupled in a single plane. At least two of the piezoelectric sensing elements have measurement axes that are orthogonal to each other. The clamping platen is for securing the circuit board panel to the exciter base. The exciter base includes a plurality of electrical connections for simultaneously testing each of one or more piezoelectric accelerometer assemblies on the circuit board panel.

In some implementations, the one or more piezoelectric accelerometer assemblies includes two or more piezoelectric accelerometer assemblies.

In some implementations, the electrical connections include spring-loaded pins coupled on the exciter base for contacting connection points on the circuit board panel. In some implementations, the spring-loaded pins are arranged to simultaneously contact power and signal connection points for each piezoelectric accelerometer assembly on the circuit board panel.

In some implementations, the exciter base is configured to generate vibrations in three orthogonal directions to test the piezoelectric accelerometer assemblies. In some implementations, the clamping platen is configured to apply uniform pressure across the circuit board panel to ensure consistent contact between the electrical connections and the accelerometer assemblies during vibration testing.

In some implementations, the fixture further includes a control system configured to sequentially generate vibrations in the fixture in directions having a vector component in the measurement axis of at least one piezoelectric sensing element.

In some implementations, the fixture further includes a control system configured to generate vibrations in the fixture in a direction having vector components in the measurement axes of at least two of the piezoelectric sensing elements. In some implementations, each piezoelectric accelerometer assembly includes three piezoelectric sensing elements having measurement axes in three orthogonal axes. In some implementations, the fixture further includes a control system configured to generate vibrations in the fixture in a direction having vector components in the measurement axes of the three piezoelectric sensing elements.

Various other implementations provide a method of testing piezoelectric accelerometers. The method includes providing a fixture configured for testing and calibrating piezoelectric accelerometers, the fixture including an exciter base, a rigid circuit board panel containing one or more piezoelectric accelerometer assemblies, each piezoelectric accelerometer assembly including piezoelectric sensing elements coupled in a single plane, wherein at least two of the piezoelectric sensing elements have measurement axes that are orthogonal to each other, and a clamping platen for securing the circuit board panel to the exciter base, wherein the exciter base includes a plurality of electrical connections for simultaneously testing each of one or more piezoelectric accelerometer assemblies on the circuit board panel, and causing the exciter base to generate vibrations in the fixture in a direction having a vector component in the measurement axis of at least one of the piezoelectric sensing elements.

In some implementations, the one or more piezoelectric accelerometer assemblies includes two or more piezoelectric accelerometer assemblies.

In some implementations, the electrical connections include spring-loaded pins coupled on the exciter base for contacting connection points on the circuit board panel. In some implementations, the spring-loaded pins are arranged to simultaneously contact power and signal connection points for each piezoelectric accelerometer assembly on the circuit board panel.

In some implementations, the exciter base is configured to generate vibrations in three orthogonal directions to test the piezoelectric accelerometer assemblies. In some implementations, the clamping platen is configured to apply uniform pressure across the circuit board panel to ensure consistent contact between the electrical connections and the piezoelectric accelerometer assemblies during vibration testing.

In some implementations, the method further includes sequentially generating vibrations in the fixture in other directions having a vector component in the measurement axis of at least one piezoelectric sensing element.

In some implementations, the direction of the generated vibrations has vector components in the measurement axes of at least two of the piezoelectric sensing elements. In some implementations, each piezoelectric accelerometer assembly includes three piezoelectric sensing elements having measurement axes in three orthogonal axes. In some implementations, the direction of the generated vibrations has vector components in the measurement axes of the three piezoelectric sensing elements.

In some implementations, the method further includes determining a correction value based on a sensed magnitude of the generated vibrations by the piezoelectric sensing element compared to an expected magnitude of the generated vibrations.

### BRIEF DESCRIPTION OF DRAWINGS

Example features and implementations of the present disclosure are disclosed in the accompanying drawings. However, the present disclosure is not limited to the precise arrangements and instrumentalities shown. Similar elements in different implementations are designated using the same reference numerals.

FIG. 1 illustrates an exploded isometric view of a horizontal piezoelectric sensing element assembly, according to one implementation.

FIG. 2 illustrates an exploded isometric view of a vertical piezoelectric sensing element assembly, according to another implementation.

FIG. 3 illustrates an isometric view of a piezoelectric accelerometer assembly mounted on a circuit board, according to one implementation.

FIG. 4 illustrates an isometric view of the piezoelectric accelerometer assembly of FIG. 3.

FIG. 5 illustrates an isometric view of the piezoelectric accelerometer assembly of FIG. 3 with a conductive shield.

FIG. 6 illustrates a top isometric view of a circuit board panel containing multiple piezoelectric accelerometer assemblies of FIG. 3, according to one implementation.

FIG. 7 illustrates a bottom isometric view of the circuit board panel containing multiple piezoelectric accelerometer assemblies of FIG. 6.

FIG. 8 illustrates an exploded isometric view of a test fixture assembly for piezoelectric accelerometers, according to one implementation.

FIG. 9 illustrates an isometric view of the test fixture of FIG. 8 in an assembled configuration.

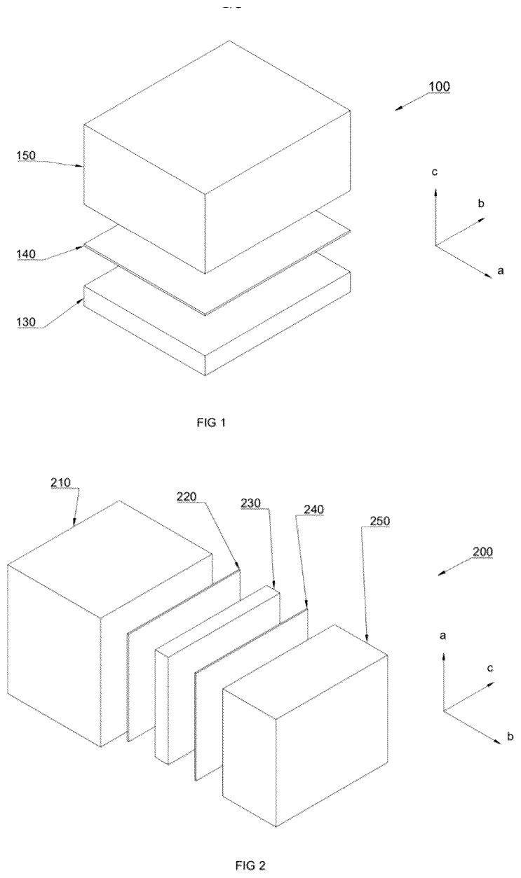

### DETAILED DESCRIPTION

The present disclosure relates to piezoelectric accelerometer assemblies and methods of manufacturing and testing such assemblies. In various implementations, a piezoelectric accelerometer assembly may include a rigid circuit board with multiple piezoelectric sensing elements coupled directly to the circuit board in a single plane. The piezoelectric sensing elements may be arranged such that at least two of the sensing elements have measurement axes that are orthogonal to each other. In some cases, three piezoelectric sensing elements may be arranged to measure vibration in three orthogonal axes.

The piezoelectric accelerometer assembly may also include a charge amplifier circuit coupled to the circuit board. The charge amplifier circuit may be electrically coupled to the piezoelectric sensing elements to process the signals generated by the sensing elements in response to acceleration or vibration.

This configuration allows for a compact, multi-axis accelerometer design that can be manufactured using standard surface mount technology (SMT) processes. The direct coupling of the piezoelectric sensing elements to a single rigid circuit board in a planar arrangement may provide advantages in terms of manufacturability, reliability, and performance compared to traditional piezoelectric accelerometer designs. Due to the limitations of MEMS sensors, piezoelectric accelerometers are required in many circumstances. However, current manufacturing costs of piezoelectric accelerometers are higher than the manufacturing costs of MEMS sensors, and current manufacturing methods for piezoelectric accelerometers cannot fill the growing demand in the market. To address these issues, the piezoelectric accelerometer assemblies, methods of manufacturing, and methods of testing provide for lower cost and faster manufacturing.

The piezoelectric accelerometer assemblies described herein may be useful for measuring vibration and acceleration in various industrial, automotive, aerospace, and consumer applications where precise multi-axis motion sensing is desired. The methods of manufacturing and testing these assemblies may enable efficient production and quality control of such sensors at scale.

Various implementations include a piezoelectric accelerometer assembly. The assembly includes a rigid circuit board, a plurality of piezoelectric sensing elements, and a charge amplifier circuit. The plurality of piezoelectric sensing elements are coupled directly on the circuit board in a single plane. At least two of the piezoelectric sensing elements have measurement axes that are orthogonal to each other. The charge amplifier circuit is coupled on the circuit board and electrically coupled to the piezoelectric sensing elements.

Various other implementations include a method of manufacturing a piezoelectric accelerometer. The method includes providing a rigid circuit board, coupling a plurality of piezoelectric sensing elements directly on the circuit board in a single plane using surface mount technology (SMT), and coupling a charge amplifier circuit on the circuit board. At least two of the piezoelectric sensing elements have measurement axes that are orthogonal to each other.

Various other implementations include a fixture configured for testing and calibrating piezoelectric accelerometers. The fixture includes an exciter base, a rigid circuit board panel, and a clamping platen. The rigid circuit board panel contains one or more piezoelectric accelerometer assemblies. Each piezoelectric accelerometer assembly includes piezoelectric sensing elements coupled in a single plane. At least two of the piezoelectric sensing elements have measurement axes that are orthogonal to each other. The clamping platen is for securing the circuit board panel to the exciter base. The exciter base includes a plurality of electrical connections for simultaneously testing each of one or more piezoelectric accelerometer assemblies on the circuit board panel.

Various other implementations include a method of testing piezoelectric accelerometers. The method includes providing a fixture configured for testing and calibrating piezoelectric accelerometers and causing the exciter base to generate vibrations in the fixture in a direction having a vector component in the measurement axis of at least one of the piezoelectric sensing elements. The fixture includes an exciter base, a rigid circuit board panel containing one or more piezoelectric accelerometer assemblies, and a clamping platen for securing the circuit board panel to the exciter base. Each piezoelectric accelerometer assembly includes piezoelectric sensing elements coupled in a single plane, wherein at least two of the piezoelectric sensing elements have measurement axes that are orthogonal to each other. The exciter base includes a plurality of electrical connections for simultaneously testing each of one or more piezoelectric accelerometer assemblies on the circuit board panel.

FIGS. 3-5 show an example of a piezoelectric accelerometer assembly 1000 having aspects according to various implementations. The assembly 1000 includes a rigid circuit board 300, three piezoelectric sensing elements 100x, 100y, 200z, and a charge amplifier circuit 310.

FIG. 1 shows an exploded view of a horizontal piezoelectric sensing element 100 included in the piezoelectric accelerometer assembly 1000. The horizontal piezoelectric sensing element 100 includes a piezoelectric plate 130. The piezoelectric plate 130 may utilize shear mode polarization. A seismic mass 150 is coupled to the piezoelectric plate 130. A conductive bonding layer 140 secures the piezoelectric plate 130 to the seismic mass 150. The conductive bonding layer 140 comprises solder or conductive adhesive.

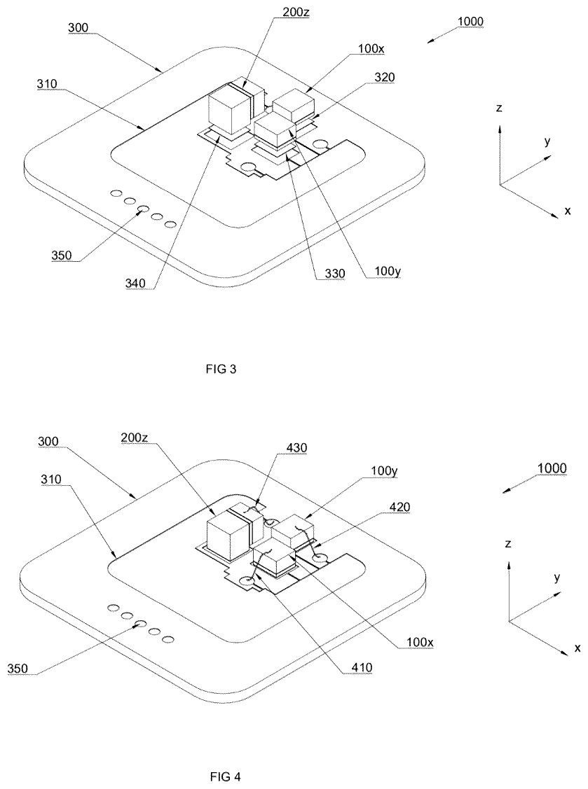

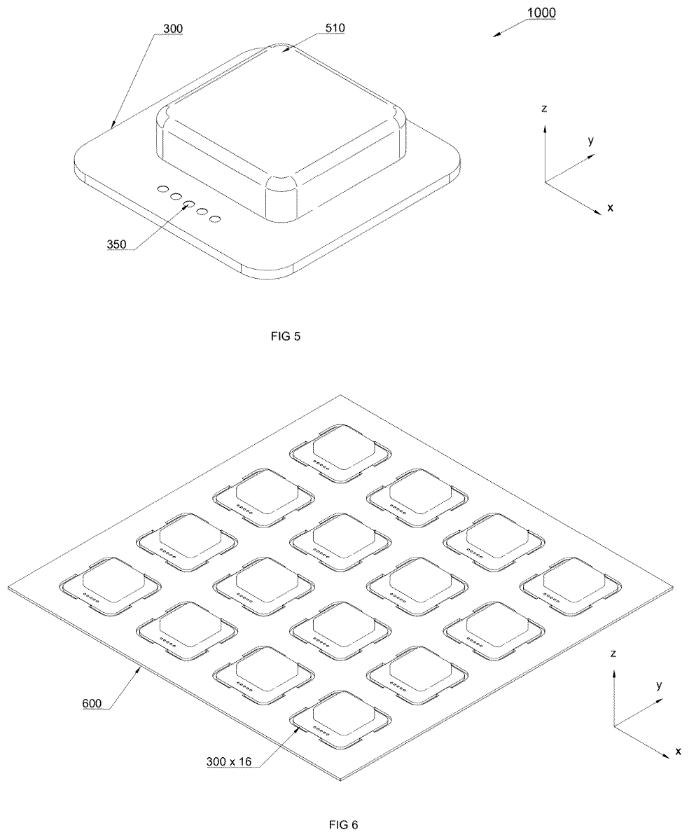

As shown in FIGS. 3 and 4, the horizontal piezoelectric sensing elements 100x, 100y can be configured to measure vibration in directions parallel to a plane of a circuit board 300. For example, a horizontal piezoelectric sensing element x 100x may be arranged to measure vibration along one axis parallel to the circuit board 300 plane, while a horizontal piezoelectric sensing element y 100y may be arranged to measure vibration along an orthogonal axis parallel to the circuit board 300 plane.

FIG. 1 shows an exploded view of a vertical piezoelectric sensing element 200 included in the piezoelectric accelerometer assembly 1000. The vertical piezoelectric sensing element 200 also includes a piezoelectric plate 230 utilizing shear mode polarization. The vertical piezoelectric sensing element 200 comprises a mounting base 210. The piezoelectric plate 230 is coupled to the mounting base 210. A seismic mass 250 is coupled to an opposite side of the piezoelectric plate 230 from the mounting base 210.

As shown in FIGS. 3 and 4, the vertical piezoelectric sensing element 200z can be configured to measure vibration in a direction orthogonal to the plane of the circuit board 300. In some cases, the mounting base 210 of the vertical piezoelectric sensing element 200z may be coupled directly to the circuit board 300.

For both horizontal and vertical piezoelectric sensing elements 100, 200, the seismic mass 150, 250 may be made of conductive material. This may allow for electrical connections to be made directly to the seismic mass 150, 250.

The piezoelectric accelerometer assembly 1000 shown in FIGS. 3-5 further includes a second conductive bonding layer 320, 330, 340 securing each of the piezoelectric sensing elements 100x, 100y, 200z to the circuit board 300. This second conductive bonding layer 320, 330, 340 may also comprise solder or conductive adhesive.

The piezoelectric accelerometer assembly 1000 includes three piezoelectric sensing elements 100x, 100y, 200z each arranged orthogonally relative to each other. As shown in FIGS. 3 and 4, two of the three piezoelectric sensing elements may be horizontal piezoelectric sensing elements 100x, 100y coupled to the circuit board 300 to measure vibration in directions parallel to the circuit board 300 plane. The third piezoelectric sensing element is a vertical piezoelectric sensing element 200z coupled to the circuit board 300 to measure vibration in a direction orthogonal to the circuit board 300 plane.

This arrangement of piezoelectric sensing elements 100x, 100y, 200z allows for measurement of vibration or acceleration along three orthogonal axes while maintaining a compact assembly with all sensing elements coupled to a single circuit board 300.

The piezoelectric accelerometer assembly 1000 shown in FIGS. 3-5 includes a circuit board 300. The circuit board 300 may be made of sufficiently rigid material to effectively transmit vibration. In some cases, the circuit board 300 comprises FR4 or ceramic material. The term “rigid,” as used herein with respect to the circuit board 300, means that the components coupled to the circuit board 300 are all coupled to a single, stiff circuit board 300 that does not include any flexible portions, such as flexible ribbon.

A charge amplifier circuit 310 is coupled to the circuit board 300. The charge amplifier circuit 310 is electrically coupled to the piezoelectric sensing elements 100x, 100y, 200z to process signals generated in response to acceleration or vibration.

In some implementations, the piezoelectric sensing elements 100x, 100y, 200z may be mounted directly on the circuit board 300 using conductive bonding materials. For example, a first conductive bond 320 and a second conductive bond 330 may secure horizontal piezoelectric sensing elements 100x, 100y to the circuit board 300. A vertical conductive bond 340 may secure a vertical piezoelectric sensing element 200z to the circuit board 300. The conductive bonding materials may comprise solder or conductive adhesive.

As shown in FIG. 4, the piezoelectric accelerometer assembly 1000 may further include electrical connection wires coupling each seismic mass 150, 250 of the piezoelectric sensing elements 100x, 100y, 200z to the charge amplifier circuit 310. For example, a first electrical wire 410, a second electrical wire 420, and a third electrical wire 430 may electrically connect the respective seismic masses 150, 250 to the charge amplifier circuit 310. In some cases, the electrical connection wires 410, 420, 430 may be designed to maintain rigidity without imparting significant force on the seismic masses 150, 250 when under vibration load. This may help prevent corruption of the resulting vibration measurements.

The circuit board 300 may include connection points 350 for power and signal circuits. In some implementations, the circuit board 300 may comprise a ground plane on a bottom layer. The circuit board 300 may also include power and signal circuits on an intermediary layer. The connection points 350 for the power and signal circuits may be accessible outside a conductive shield 510 that may be positioned over the piezoelectric sensing elements 100x, 100y, 200z and charge amplifier circuit 310.

As shown in FIG. 5, the piezoelectric accelerometer assembly 1000 may further include a conductive shield 510. The conductive shield 510 may be positioned over the piezoelectric sensing elements 100x, 100y, 200z and the charge amplifier circuit 310 on the circuit board 300. The conductive shield 510 provides protection against electromagnetic interference (EMI) and radio frequency interference (RFI) for the sensitive components of the accelerometer assembly 1000.

In some implementations, the conductive shield 510 may be placed using automated assembly equipment. For example, standard pick and place electronics assembly machines equipped with fluid dispensing options may be used to position and secure the conductive shield 510 over the piezoelectric sensing elements 100x, 100y, 200z and charge amplifier circuit 310. This automated placement may help ensure consistent and precise shielding for each accelerometer assembly 1000.

The conductive shield 510 can be designed to cover the piezoelectric sensing elements 100x, 100y, 200z, the charge amplifier circuit 310, the first conductive bond 320, the second conductive bond 330, the vertical conductive bond 340, the first electrical wire 410, the second electrical wire 420, and the third electrical wire 430. In some cases, the conductive shield 510 may be shaped to allow access to the connection points 350 for power and signal circuits.

The placement of the conductive shield 510 may complete the assembly of the piezoelectric accelerometer assembly 1000. The resulting shielded assembly provides a compact, multi-axis accelerometer with protection against electromagnetic interference, suitable for various sensing applications.

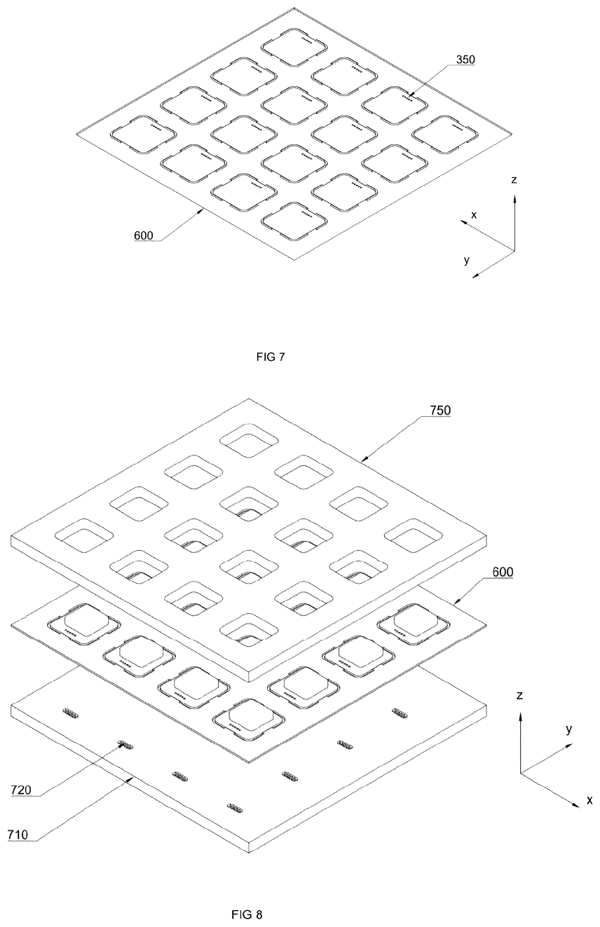

As shown in FIGS. 6 and 7, the manufacturing process for the piezoelectric accelerometer assembly 1000 may involve producing multiple assemblies simultaneously on a circuit board panel 600. In some cases, the circuit board panel 600 may be a panelized array containing multiple piezoelectric accelerometer assemblies 1000. This approach may allow for efficient mass production of the accelerometer assemblies 1000.

The manufacturing process may begin with providing a rigid circuit board panel 600. In some implementations, a plurality of piezoelectric sensing elements 100x, 100y, 200z may be coupled directly on the circuit board panel 600 in a single plane using surface mount technology (SMT). The charge amplifier circuit 310 may also be coupled on the circuit board panel 600 using SMT techniques.

In some cases, a conductive bonding material may be applied to couple each piezoelectric sensing element 100x, 100y, 200z to the circuit board panel 600. The conductive bonding material may comprise conductive adhesive, solder, or other conductive bonding medium. The conductive bonding material may be applied using fluid printing or dispensing equipment.

After the piezoelectric sensing elements 100x, 100y, 200z and charge amplifier circuit 310 are mounted, each piezoelectric sensing element 100x, 100y, 200z may be electrically coupled to the charge amplifier circuit 310 using wire bonding. The coupling of the electrical wires be performed using SMT techniques. In some implementations, heavy wire bond machinery may be used to attach the electrical connection wires, such as the first electrical wire 410, the second electrical wire 420, and the third electrical wire 430.

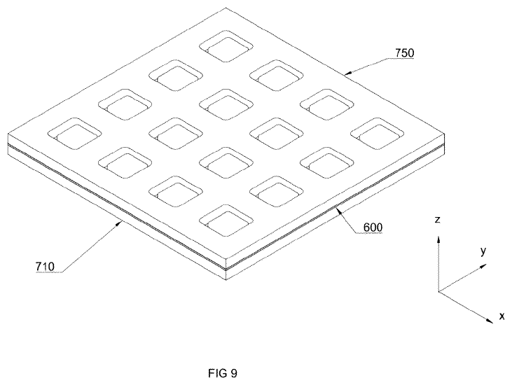

For testing and calibrating the piezoelectric accelerometer assemblies 1000, a test fixture 800 may be used. FIGS. 8 and 9 illustrate an example of a test fixture 800 having aspects according to various implementations. The test fixture 800 includes an exciter base 710, the circuit board panel 600 containing one or more piezoelectric accelerometer assemblies 1000, and a clamping platen 750.

The exciter base 710 includes a plurality of electrical connections for simultaneously testing each of the piezoelectric accelerometer assemblies 1000 on the circuit board panel 600. In some implementations, the electrical connections may comprise spring loaded pins 720 coupled on the exciter base 710. The spring loaded pins 720 may be arranged to contact the connection points 350 on the circuit board panel 600. These connection points 350 may include power and signal connection points for each piezoelectric accelerometer assembly 1000.

The clamping platen 750 is used for securing the circuit board panel 600 to the exciter base 710. The clamping platen 750 include a plurality of openings through which the components of each piezoelectric accelerometer assembly 1000 can be disposed. In some cases, the clamping platen 750 may be configured to apply uniform pressure across the circuit board panel 600. This uniform pressure may help ensure consistent contact between the spring loaded pins 720 and the connection points 350 on the circuit board panel 600 during vibration testing. Applying uniform pressure ensures that the required stiffness is maintained to preserve the integrity of the vibration measurement. Mass and stiffness determine the natural frequency of the assembly, so it is important that the test fixtures disclosed herein provide sufficient stiffness while limiting the addition of mass to reduce corruption of measurements during testing.

The exciter base 710 may be configured to generate vibrations in three orthogonal directions to test the piezoelectric accelerometer assemblies 1000. In some implementations, the test fixture 800 may include a control system configured to generate vibrations in the exciter base 710 in a direction having vector components in the measurement axes of one of the piezoelectric sensing elements 100x, 100y, 200z. In some implementations, the test fixture 800 may include a control system configured to generate vibrations in the exciter base 710 in a direction having vector components in the measurement axes of at least two of the piezoelectric sensing elements 100x, 100y, 200z. In some cases, the direction of the generated vibrations may have vector components in the measurement axes of all three piezoelectric sensing elements 100x, 100y, 200z in a triaxial accelerometer assembly 1000.

The testing procedure may involve causing the exciter base 710 to generate vibrations in the test fixture 800 in a direction having a vector component in the measurement axis of at least one of the piezoelectric sensing elements 100x, 100y, 200z. In this way, at least one of the piezoelectric sensing elements 100x, 100y, 200z in each of the piezoelectric accelerometer assemblies 1000 of the circuit board panel 600 are tested simultaneously. The testing procedure may further comprise sequentially generating vibrations in the test fixture 800 in other directions having a vector component in the measurement axis of at least one piezoelectric sensing element 100x, 100y, 200z such that each piezoelectric sensing element 100x, 100y, 200z is tested. The sequential vibration testing allows a first group of piezoelectric sensing elements 100x, 100y, 200z with parallel measurement axes on the same circuit board panel 600 to be tested together, then a second group of piezoelectric sensing elements 100x, 100y, 200z with parallel measurement axes that are orthogonal to the measurement axes of the first group can be tested together, then a third group of piezoelectric sensing elements 100x, 100y, 200z with parallel measurement axes that are orthogonal to the measurement axes of both the first and second groups can be tested together.

During the testing procedure, the sensed magnitude of the generated vibrations by each piezoelectric sensing element 100x, 100y, 200z may be compared to an expected magnitude of the generated vibrations. In some cases, a correction value may be determined based on this comparison. This correction value may be used for calibrating the piezoelectric accelerometer assemblies 1000. In some implementations, the correction value is an offset value to be added or subtracted from the sensed magnitude by a piezoelectric sensing element 100x, 100y, 200z. In some implementations, the correction value is a multiplication factor for the sensed magnitude by a piezoelectric sensing element 100x, 100y, 200z to be multiplied by or divided by. In some implementations, the correction value is any number or plurality of numbers to be mathematically applied to the piezoelectric sensing element 100x, 100y, 200z calibrate a piezoelectric sensing element 100x, 100y, 200z.

By using the test fixture 800 with the circuit board panel 600 containing multiple piezoelectric accelerometer assemblies 1000, the testing and calibration process may be performed simultaneously for multiple accelerometer assemblies 1000. This approach may significantly increase the efficiency of the manufacturing and testing process for the piezoelectric accelerometer assemblies 1000.

The piezoelectric sensing elements 100x, 100y, 200z, circuit board 300, charge amplifier 310, and conductive shield 510 work together to enable the function of the piezoelectric accelerometer 1000.

The piezoelectric sensing elements 100x, 100y, 200z generate electrical charges in response to acceleration or vibration. These elements may be mounted directly on the rigid circuit board 300 in a single plane using SMT. In some cases, three piezoelectric sensing elements 100x, 100y, 200z may be arranged orthogonally to measure acceleration along three axes.

The circuit board 300 provides a stable platform for mounting the components and may be made of a sufficiently rigid material to effectively transmit vibrations to the sensing elements 100x, 100y, 200z without corrupting the signal. A rigid circuit board 300 allows the attachment of circuitry to the sensor such that the signal is not corrupted by adding mass or reducing stiffness. The circuit board 300 may also include conductive traces to route signals and power.

The charge amplifier circuit 310, which may also be mounted on the circuit board 300, converts the small electrical charges generated by the piezoelectric elements 100x, 100y, 200z into usable voltage signals. This amplification allows for accurate measurement of acceleration or vibration.

A conductive shield 510 may be positioned over the piezoelectric sensing elements 100x, 100y, 200z and charge amplifier 310 on the circuit board 300. This shield 510 may help protect the sensitive components from electromagnetic interference, which could otherwise affect the accuracy of measurements.

In operation, when the accelerometer 1000 experiences acceleration or vibration, the piezoelectric sensing elements 100x, 100y, 200z generate electrical charges. These charges are then amplified by the charge amplifier circuit 310. The resulting voltage signals may be proportional to the acceleration experienced by the device. The conductive shield 510 helps ensure that these signals are not corrupted by external electromagnetic interference.

The arrangement of multiple sensing elements 100x, 100y, 200z in orthogonal orientations may allow the accelerometer 1000 to measure acceleration in multiple axes simultaneously. This capability can be useful for applications requiring multi-dimensional motion sensing.

In some cases, the accelerometer 1000 may include connection points 350 on the circuit board 300 for power input and signal output. These connection points 350 may allow the accelerometer 1000 to be integrated into larger systems or connected to data acquisition equipment for further processing and analysis of the acceleration data.

A number of example implementations are provided herein. However, it is understood that various modifications can be made without departing from the spirit and scope of the disclosure herein. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. Although the terms “comprising” and “including” have been used herein to describe various implementations, the terms “consisting essentially of” and “consisting of” can be used in place of “comprising” and “including” to provide for more specific implementations and are also disclosed.

Disclosed are materials, systems, devices, methods, compositions, and components that can be used for, can be used in conjunction with, can be used in preparation for, or are products of the disclosed methods, systems, and devices. These and other components are disclosed herein, and it is understood that when combinations, subsets, interactions, groups, etc. of these components are disclosed that while specific reference of each various individual and collective combinations and permutations of these components may not be explicitly disclosed, each is specifically contemplated and described herein. For example, if a device is disclosed and discussed each and every combination and permutation of the device are disclosed herein, and the modifications that are possible are specifically contemplated unless specifically indicated to the contrary. Likewise, any subset or combination of these is also specifically contemplated and disclosed. This concept applies to all aspects of this disclosure including, but not limited to, steps in methods using the disclosed systems or devices. Thus, if there are a variety of additional steps that can be performed, it is understood that each of these additional steps can be performed with any specific method steps or combination of method steps of the disclosed methods, and that each such combination or subset of combinations is specifically contemplated and should be considered disclosed.

1. A piezoelectric accelerometer assembly, comprising:
a rigid circuit board;
a plurality of piezoelectric sensing elements coupled directly on the circuit board in a single plane, wherein at least two of the piezoelectric sensing elements have measurement axes that are orthogonal to each other; and
a charge amplifier circuit coupled on the circuit board and electrically coupled to the piezoelectric sensing elements.

2. The piezoelectric accelerometer assembly of claim 1, wherein the plurality of piezoelectric sensing elements comprises three piezoelectric sensing elements arranged to measure vibration in three orthogonal axes.

3. The piezoelectric accelerometer assembly of claim 2, wherein two of the three piezoelectric sensing elements are coupled to the circuit board in a configuration to measure vibration in a direction parallel to the single plane and one of the three piezoelectric sensing elements is coupled to the circuit board in a configuration to measure vibration in a direction orthogonal to the single plane.

4. The piezoelectric accelerometer assembly of claim 1, wherein each piezoelectric sensing element comprises:
a piezoelectric plate;
a seismic mass; and
a conductive bonding layer securing the piezoelectric plate to the seismic mass.

5. The piezoelectric accelerometer assembly of claim 4, wherein the conductive bonding layer is a first conductive bonding layer, wherein each piezoelectric sensing element further comprises:
a second conductive bonding layer securing the piezoelectric sensing element to the circuit board.

6. The piezoelectric accelerometer assembly of claim 4, further comprising electrical connection wires electrically coupling each seismic mass to the charge amplifier circuit.

7. The piezoelectric accelerometer assembly of claim 1, further comprising a conductive shield positioned over the piezoelectric sensing elements and the charge amplifier circuit.

8. The piezoelectric accelerometer assembly of claim 7, wherein the circuit board comprises a ground plane on a bottom layer and power and signal circuits on an intermediary layer, wherein connection points for the power and signal circuits are accessible outside the conductive shield.

9. A method of manufacturing a piezoelectric accelerometer, comprising:
providing a rigid circuit board;
coupling a plurality of piezoelectric sensing elements directly on the circuit board in a single plane using surface mount technology (SMT), wherein at least two of the piezoelectric sensing elements have measurement axes that are orthogonal to each other; and
coupling a charge amplifier circuit on the circuit board.

10. The method of claim 9, wherein coupling the plurality of piezoelectric sensing elements comprises coupling three piezoelectric sensing elements arranged to measure vibration in three orthogonal axes.

11. The method of claim 10, wherein coupling the three piezoelectric sensing elements comprises coupling two of the three piezoelectric sensing elements to the circuit board in a configuration to measure vibration in a direction parallel to the single plane and coupling one of the three piezoelectric sensing elements to the circuit board in a configuration to measure vibration in a direction orthogonal to the single plane.

12. The method of claim 9, further comprising applying a conductive bonding material to couple each piezoelectric sensing element to the circuit board.

13. The method of claim 12, wherein applying the conductive bonding material comprises using at least one of: conductive adhesive, solder, or other conductive bonding medium.

14. The method of claim 9, further comprising electrically coupling each piezoelectric sensing element to the charge amplifier circuit using wire bonding.

15. The method of claim 14, further comprising positioning a conductive shield over the piezoelectric sensing elements and the charge amplifier circuit on the circuit board.

16-34. (canceled)
